(19) United States
(12) Patent Application Publication
(10) Pub. No.: US 2012/0188738 A1
(43) Pub. Date: Jul. 26, 2012

(54) Integrated led in system-in-package module

(75) Inventors: Robert W. Warren, Newport Beach, CA (US); Nic Rossi, Radio City (HK)

(73) Assignee: CONEXANT SYSTEMS, INC., Newport Beach, CA (US)

(21) Appl. No.: 12/931,240

(22) Filed: Jan. 25, 2011

(51) Int. Cl. H05K 7/02; H05K 3/30

(52) U.S. Cl. 361/807; 29/832

(57) ABSTRACT

There is provided a system-in-package (SiP) module that comprises a substrate, a semiconductor die attached to the substrate, a mold compound which encapsulates the semiconductor die, and an LED (light emitting diode) component attached to the substrate, where the LED component is at least partially located within the SiP module, such that the LED component can emit lights to outside of the SiP module.

### BACKGROUND OF THE INVENTION

1. Field of the Invention

The present invention relates to System-in-Package (SiP) modules and more specifically to SiP modules with light emitting diode components.

2. Background Information

SiP modules are popular because they offer high functionality and performance in a small form factor. A SiP module can comprise bare fabricated semiconductor dies, packaged semiconductors and passive components attached to a single substrate and encapsulated by a mold compound.

For many applications, such as a USB connector module, it is desirable to provide one or more LED on the module to provide a status indicator such as a power indication or a data transfer indication. Other modules may use LEDs for other applications, such as for infrared remote controls, non-contact position sensing, optical encoders, smoke detectors, etc.

Because of the opaque nature of the mold compound in SiP modules, conventionally, LEDs are not assembled within the SiP module, but are attached to the exterior of the SiP module.

One conventional solution is to solder a surface mount device (SMD) LED on the outside of the SiP module, and at the bottom of the substrate where the connector pads are located. However, mounting an LED after the molding process is expensive, since the mounting requires an SMT (surface mount technology) automated assembly line to be setup again just for attaching one or more LEDs to the SiP module. On the other hand, manually soldering of the LEDs is also very slow and costly.

Accordingly, there is an intense need in the art for manufacturing SiP modules having LEDs in a cost and time efficient manner.

### SUMMARY OF INVENTION

There is provided methods and systems for integrating LEDs in System-in-Package (SiP) modules, substantially as shown in and/or described in connection with at least one of the figures, as set forth more completely in the claims.

### BRIEF DESCRIPTION OF DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates a side view of an embodiment of a SiP module;

FIG. 2 shows an embodiment of an LED component;

FIG. 3 illustrates a side view of an embodiment of an SiP module including an LED component which is visible through the top of the package;

FIG. 4 shows a process flow for the packaging of a SiP module with an upward facing LED;

FIG. 5 illustrates a side view of an alternative embodiment of an SiP module including an LED component which is visible through the top of the package;

FIG. 6 shows an alternate process flow for the packaging of a SiP module with an upward facing LED;

FIG. 7 illustrates a side view of an embodiment of an SiP module including an LED component which is visible through the bottom of the package;

FIG. 8 shows a process flow for the packaging of a SiP module with a downward facing LED;

FIGS. 9A and 9B illustrates a side views of an embodiment of an SiP module including an LED component which is visible through the side of the package;

FIG. 10 is a top view of an embodiment of an array of SiP modules;

FIG. 11 is a top view of the array of SiP modules after singulation;

FIG. 12 shows a process flow for the packaging of a SiP module with a sideways facing LED;

FIG. 13 is a top view of an embodiment of an array of SiP modules; and

FIG. 14 is a top view of the array of SiP modules after singulation.

### DETAILED DESCRIPTION

A detailed description of embodiments of the present invention is presented below. While the disclosure will be described in connection with these drawings, there is no intent to limit it to the embodiment or embodiments disclosed herein. On the contrary, the intent is to cover all alternatives, modifications and equivalents included within the spirit and scope of the disclosure as defined by the appended claims.

Generally, embodiments of the present invention are directed to LED components, which are integrated within the SiP modules. The SiP modules of the present invention comprise an LED component and at least one fabricated semiconductor die, both of which are electrically attached to a substrate, all within the SiP modules. In one embodiment, the LED component may be physically attached to the substrate. The LED component may be mounted using surface mount technology. The fabricated die may be mounted either using a die attach epoxy or by flip-chip technology. In the former case, bond wires are used to electrically attach the fabricated die to the substrate. The substrate can also be connected to interface pins such as pins, lands, or solder balls. The substrate can comprise metal traces which route electrical signals to various components in the SiP module including the fabricated semiconductor die and the LED component as well as the interface pins. The SiP module can also comprise prepackaged dies in a semiconductor package, which is also electrically attached to the substrate. The SiP module can also comprise passive components such as resistors, capacitors, discrete diodes and inductors, which are typically surface mounted to the substrate. The SiP module is partially, substantially or fully encapsulated into a mold compound.

In one embodiment, the LED component may face upwards and the mold compound is either molded to the top surface of the LED component or a hole is formed, by drilling or etching, in the mold compound above the LED component exposing the resin portion of the LED component.

In another embodiment, the LED component may face downwards and the substrate has a hole made either by drilling or etching exposing the resin portion of the LED component.

In another embodiment, the LED component may face sideways and is placed at the edge of the SiP module, such that during singulation, the resin portion of the LED component can be exposed.

The packaging process generally comprises attaching the various components including the fabricated semiconductor die and the LED component onto the substrate, encapsulating the package in mold compound, branding each package and singulating each package from an array of packages.

More specifically, for an upward facing LED component either the encapsulating step may mold the package up to the height of the LED component or the branding process may include forming a hole above each LED component. For a downward facing LED component the packaging process further comprises a step of forming a hole beneath each LED component prior to attaching the LED component. Finally, for the sideways facing LED component, the attaching process includes attaching the LED components so that the resin falls within the blade kerf of the singulating saw, so that during singulation the LED component is exposed. Of course, one of ordinary skilled in the art would understand that there are additional ways to expose the LED component once integrated within the SiP module.

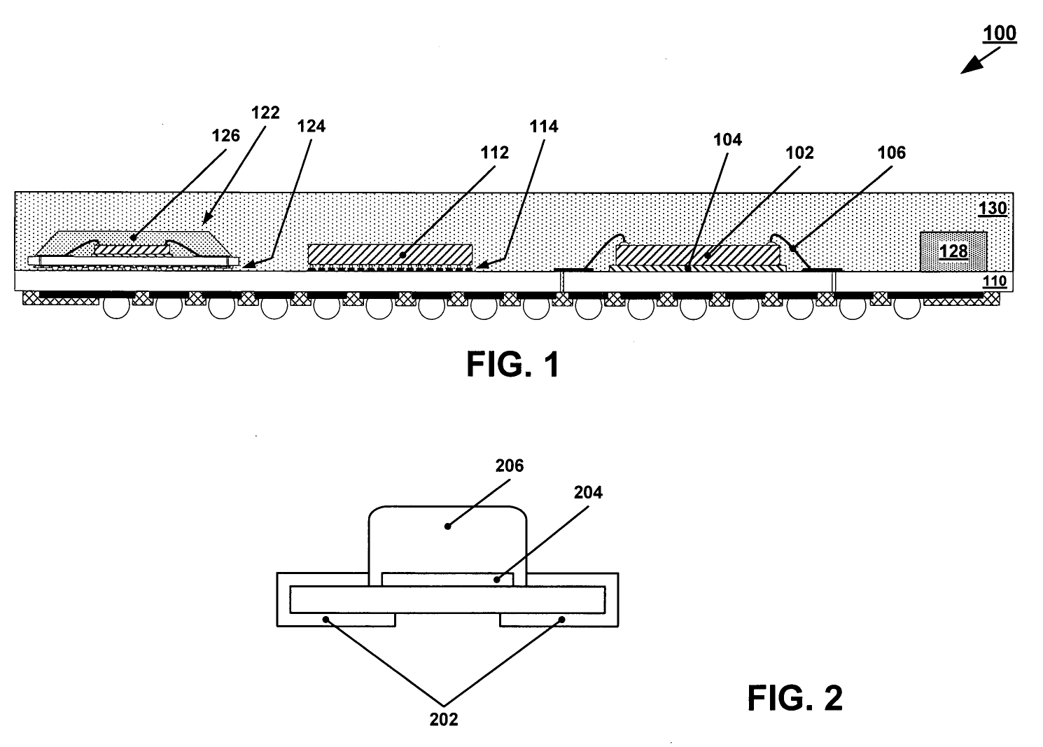

FIG. 1 illustrates a side view of an embodiment of a SiP module. In this example, it comprises bare die 102 which is attached to substrate 110 by die attach epoxy 104. The module further comprises bare die 112, which is flip-chipped to substrate 110 by solder balls 114. Alternatively a newer technique using metal pillars such as copper which are capped by solder to tin at both ends can be used instead of solder balls 114. The module further comprises semiconductor package 122, which is attached to substrate 110. In this example, package 122 is a ball grid array (BGA) package with solder balls 124 and is encapsulated in its own mold compound 126. Passive components 128 are also attached to substrate 110. The entire package is encapsulated by mold compound 130.

Shown in this example, SiP module 100 is a BGA package, but can be any number of package types including a dual in-line package (DIP) package, a pin grid array (PGA) package, a leadless chip carrier (LCC) package, a small-outline integrated circuit (SOIC) package, a plastic leaded chip carrier (PLCC) package, a plastic quad flat pack (PQFP) package, a thin quad flat pack (TQFP) package, a thin small-outline packages (TSOP) package, a land grid array (LGA) package or a Quad-Flat No-lead (QFN) package. Substrate 110 can be a metal lead frame, but can also be a laminate with metal traces. The metal traces not only facilitate the electrical attaching of the various components to the interface pins (shown as solder balls for BGA), but also provide routing between onboard components. In this fashion, fewer interface pins are often required. Bare dies 102 and 112 when present are semiconductor dies with electronic circuits fabricated upon them to perform certain functions.

Semiconductor package 122 may be included in SiP module because the desired functional module is only available in packaged form rather than as a bare die or because the packaged form is less expensive. The manner in which a package 122 is attached to substrate 110 depends on the type of package. For example, if package 122 is a BGA package, it can be attached to substrate 110 by using solder balls. If package 122 is a QFN package, it can be attached by using solder paste. A reflow oven can be used in either case to melt the solder to form the attaching.

Passive components 128 can include any number of devices including resistors, capacitors, inductors and discrete diodes. Large inductors and capacitors as well as precision resistors are very difficult to fabricate on a semiconductor die, for this reason passive components external to the semiconductor dies within a SiP module is often desirable. While it is possible to use any discrete passive component, surface mount components are widely available and well suited for SiP applications. For example, a surface mount resistor could be attached to substrate 110 with solder much in the same way a surface mount resistor would be attached to a printed circuit board. As a result the inclusion of passive components in a SiP package does not require customization of either components or processes.

It should be noted that while SiP module 100 includes die 102 which is wire bonded, die 112 which is flip-chipped, package 122 and passive components 128. Not all of these die or package types are necessarily present. Furthermore, it should be noted that although the various component types are represented in FIG. 1 and other side view figures in this disclose as linearly distributed, in reality, the components are laid out in two dimensions on the substrate. However, for the purposes of clarity, the side view representation shows the components placed linearly upon a substrate.

FIG. 2 shows an embodiment of an LED component. The LED component comprises contacts 202, LED 204, encapsulating resin 206. While any configuration of contacts can be used, LED 200 shows a typical surface mount LED configuration where the conductive material is present both on the top and the bottom of the LED component. LED 204 is a semiconductor device, which emits either visible light or infrared light when an appropriate current passes through it. Encapsulating resin 206 protects the LED. It is transparent and can serve to guide the light to some extent and also can be used to provide tinting to the light. Other embodiments of an LED may use more than two contacts. Because of the application of LEDs to PCBs have many orientations, surface mount LEDs have different arrangements of contacts to facilitate easier orientation of the LED to the surface it is mounted. LEDs that are mounted facing upwards, facing downwards, and facing sideways relative to the surface are widely available.

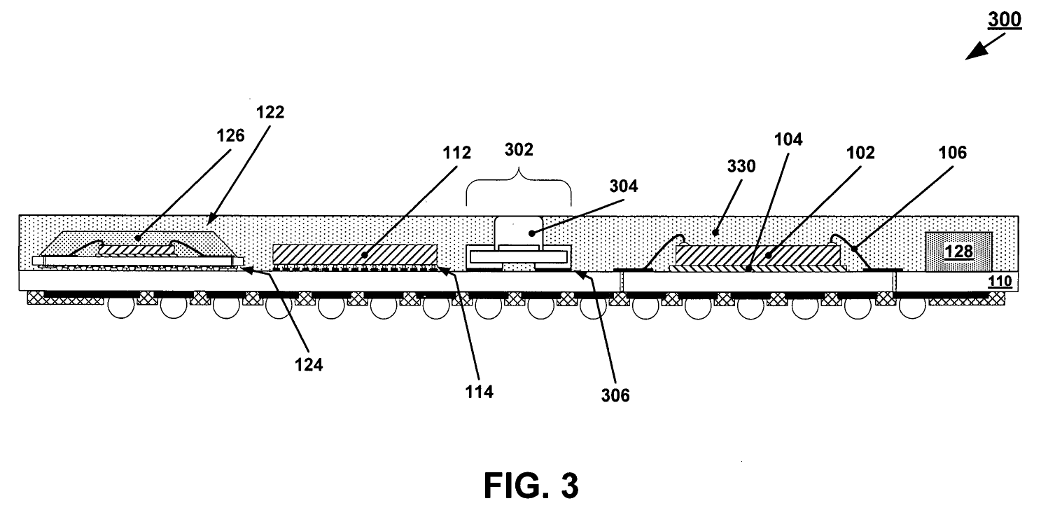

FIG. 3 illustrates a side view of an embodiment of a SiP module including an LED component, which can emit light through the top of the package to the outside of the package and/or be made visible through the top of the package. SiP module 300 comprises substrate 110 and bare die 102 with die attach epoxy 104 to attach die 102 to substrate 110. Bare die 102 is electrically attached to substrate 110 with wire bonds 106. Module 300 further comprises bare die 112, which is flip-chipped to substrate 110 by solder balls or metal pillars 114. Module 300 further comprises semiconductor package 122, which is attached substrate 110. Passive components 128 are also surface mounted to substrate 110. Module 300 further comprises LED component 302, which is oriented with upward facing. LED component comprises resin 304, which faces upwards. LED component 302 is surface mounted to substrate 110 by solder 306. The entire package may be fully, substantially or partially encapsulated by mold compound 330.

Components such as bare die 102, bare die 106, package 122 and passive components 128 need not all be present, but are shown here for illustrative purposes. Mold compound 330 is molded into the package, such that the LED leaving resin 304 is left exposed. This may accomplished by, for example, having mold compound 330 up to the height of LED component 302 such that resin 304 remains exposed, not molding the area, where LED component 302 is located, using non-opaque molding, and the like.

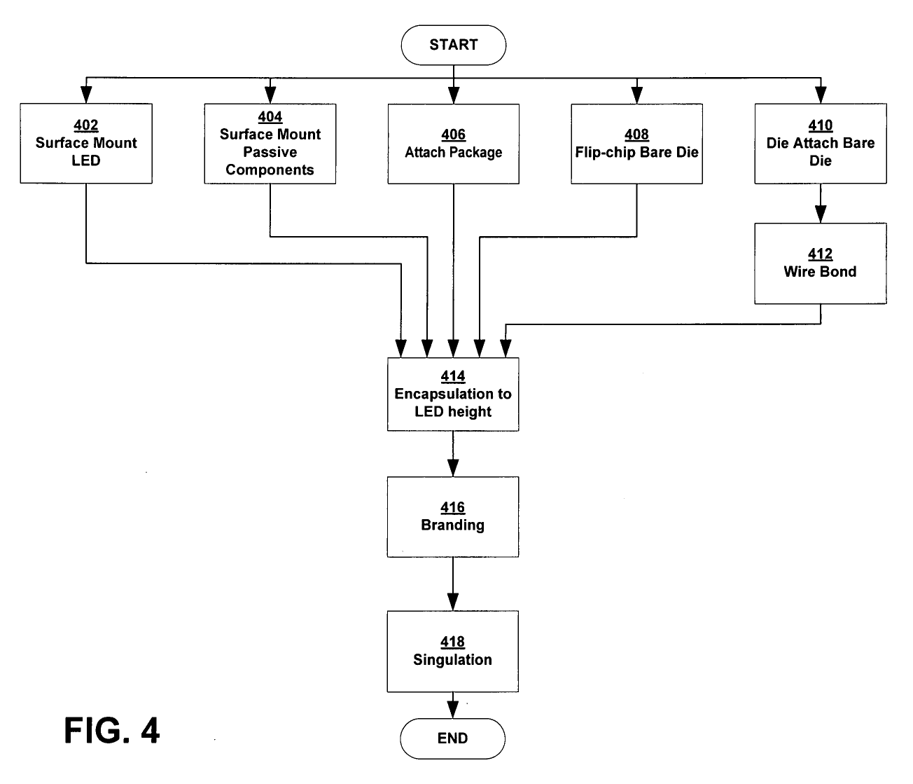

FIG. 4 shows a process flow for the packaging of a SiP module with an upward facing LED. At step 402, the LED is surface mounted in an upward facing orientation. At step 404, any passive components are surface mounted. At step 406, any semiconductor packages are attached. At step 408, any bare die is flip-chipped onto the substrate. At step 410, any bare die is die attached to the substrate. At step 412, any bare die is wire bonded. These steps are shown in parallel because they can be performed in any order. However, a common ordering is to surface mount the LED and passive components first, attach the semiconductor package next, flip-chip any bare die after that and die attach any bare die after that. It should also be noted that these steps may be combined. For example, for surface mounting components and flip chipping. Both steps call for the placement of solder or other material first, application of the component or die, and using a reflow oven to melt the solder. In some instances, surface mounting and flip-chipping can take place simultaneously.

At step 414, the package is encapsulated by mold compound, such that resin 304 is left exposed, as discussed above. Step 414 shows one example, where mold compound is provided up to the height of the LED component, or below a top edge of resin 304. At step 416, a laser used to etch branding information to the surface of the package. For example, it is common to etch the component part number, manufacturer and place of manufacture on the surface of the package. In most packaging processes, packages are assembled as an array. In such a case, the array of packages is singulated at step 418 into individual packages. The singulation is commonly performed either by punch singulation or by saw singulation, where the individual packages are broken apart by a punch or sawn apart.

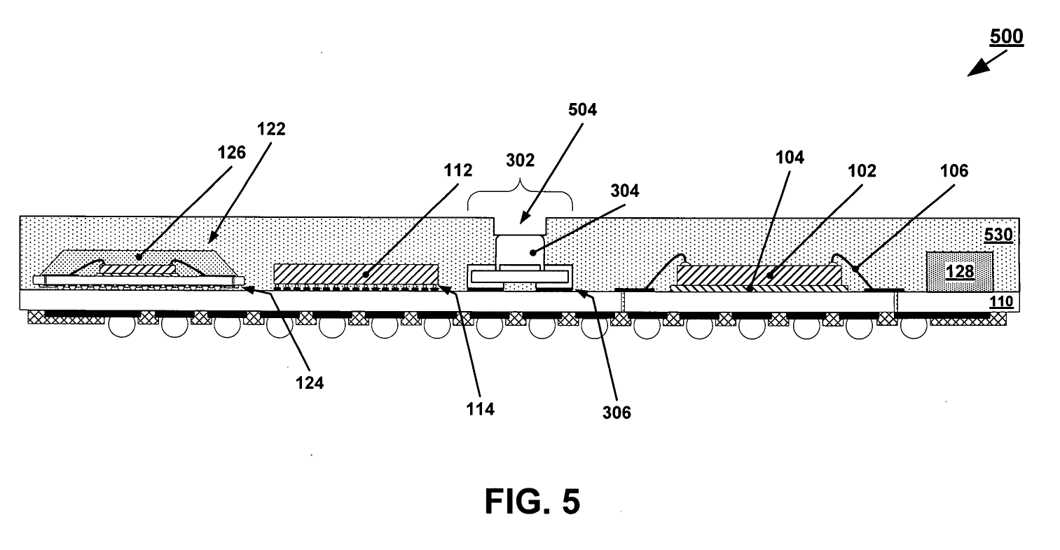

Under certain circumstances it may be difficult to mold the package precisely to the height of the LED. To do so would mean using a very precise mold, which may increase the cost of packaging. Alternatively, the LED component may not be the tallest component packages. For example, a prepackaged semiconductor or a large surface mounted capacitor could be larger. In either case, the mold compound would could completely encapsulate the LED component, and not leaving the LED resin exposed. FIG. 5 of the present application described an alternative embodiment for exposing the LED component.

FIG. 5 illustrates a side view of an alternative embodiment of a SiP module including an LED component, which can emit light through the top of the package to the outside of the package and/or be made visible through the top of the package. As in the previous examples, SiP module 500 is shown comprising a representative wire bonded bare die (die 102), a representative flip chipped bare die (die 112), a representative semiconductor package (package 122) and representative passive components (128), which are all appropriately mounted onto substrate 110. In addition, module 500 further comprises LED component 302, which is oriented with upward facing. LED component comprises resin 304, which faces upwards. LED component 302 is surface mounted to substrate 110 by solder 306. The package may be fully, substantially or partially encapsulated by mold compound 530. Unlike the example in FIG. 3, opening 504 in mold compound 530 is formed for exposing resin 304. Opening 504 can be made after molding by using a CO₂ or Nd:YAG laser. It can be combined with the branding step performed during normal packaging procedures.

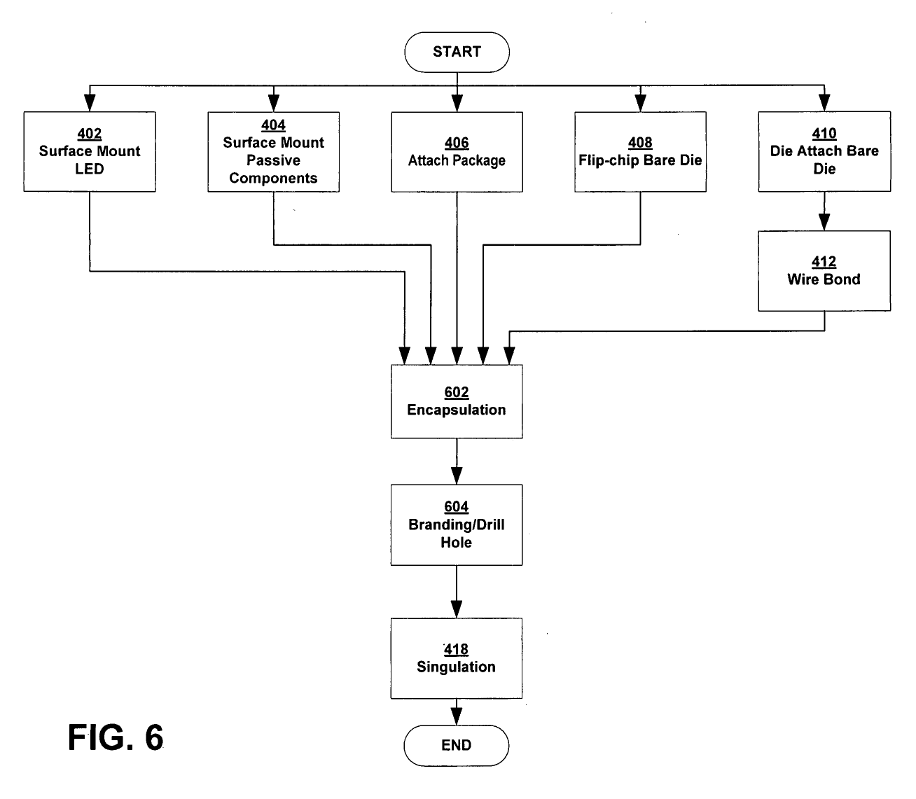

FIG. 6 shows an alternate process flow for the packaging of a SiP module with an upward facing LED. Steps 402, 404, 406, 408, 410, and 412 are as described above in FIG. 4. However, At step 602, the package may be encapsulated by mold compound completely encapsulating the package including all LED components. At step 604, a laser used to etch branding information to the surface of the package as described above for step 416. In addition during this process, the same laser in the same step can be used to drill a hole above each LED component, which has been encapsulated in the package. Because the resin portion of an LED component serves to provide chemical and mechanical protection, a little excessive milling which removes part of the resin would not affect the functionality of the LED. Once again, if the package were manufactured as part of an array of packages, the package is separated from the array of package by singulation in step 418.

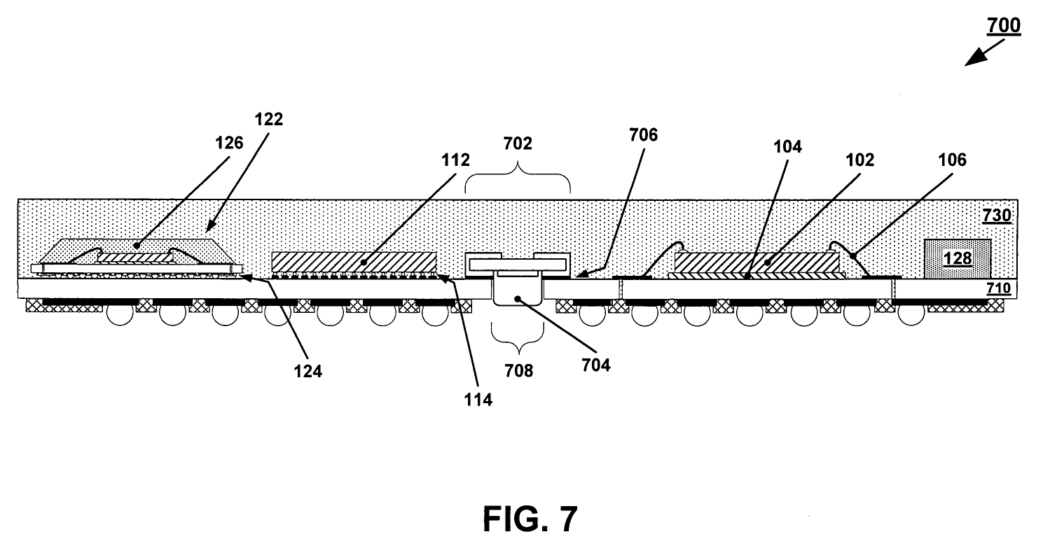

FIG. 7 illustrates a side view of an embodiment of an SiP module including an LED component, which can emit light through the bottom of the package to the outside of the package and/or be made visible through the bottom of the package. As in the previous examples, SiP module 700 is shown comprising a representative wire bonded bare die (die 102), a representative flip chipped bare die (die 112), a representative semiconductor package (package 122) and representative passive components (128)), which are all appropriately mounted onto substrate 710. Substrate 710 differs from substrate 110 described above in that substrate 710 has opening 708. As a result module 700 can comprise LED component 702 which is surface mounted with solder 706 facing downwards relative to the module 700. This leaves resin 704 exposed in the bottom of the package. Unlike the upward facing situation it does not matter whether resin 704 protrudes from the bottom or is countersunk into substrate 710. In both cases, the LED can emit light from the bottom of the package to the outside of the package and/or be made visible through the bottom of the package. Therefore, according to various embodiments of the present invention, regardless of the placement of the LED component, the LED component is at least partially located within the SiP module, and in some embodiments, the LED component is fully or substantially located within the SiP module.

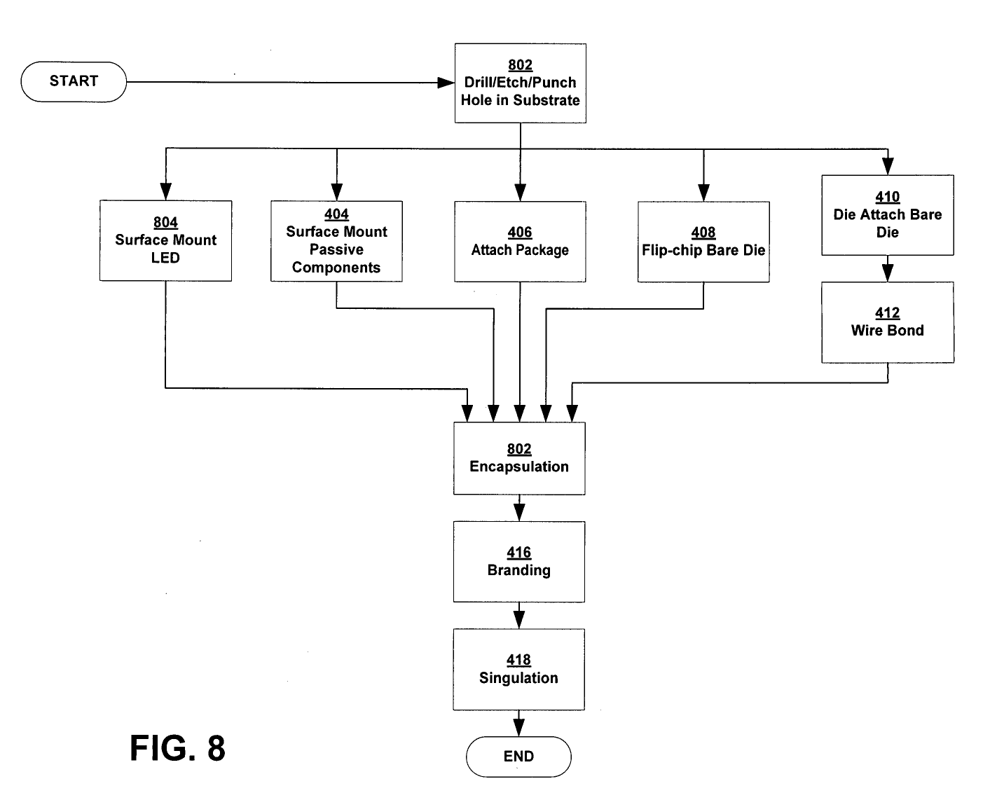

Generally speaking, the packaging procedure is the same as any SiP packaging procedure. The substrate has holes located where LEDs are to be surface mounted in a down facing manner. More specifically, FIG. 8 shows a process flow for the packaging of a SiP module with a downward facing LED. Steps 404, 406, 408, 410, 412, 602, 416 and 418 are as described above in FIG. 4 and FIG. 6. Step 804 differs from step 402 describe above in that the LED components are surface mounted facing down rather than facing up. In addition, at step 802 prior to the mounting of any components in the package, holes can be drilled into the substrate, for example by laser drilling, mechanical drilling, etching, punching, etc. In this fashion, only the additional step of making holes in the substrate is added to a SiP packaging procedure in order to accommodate the downward facing LED component.

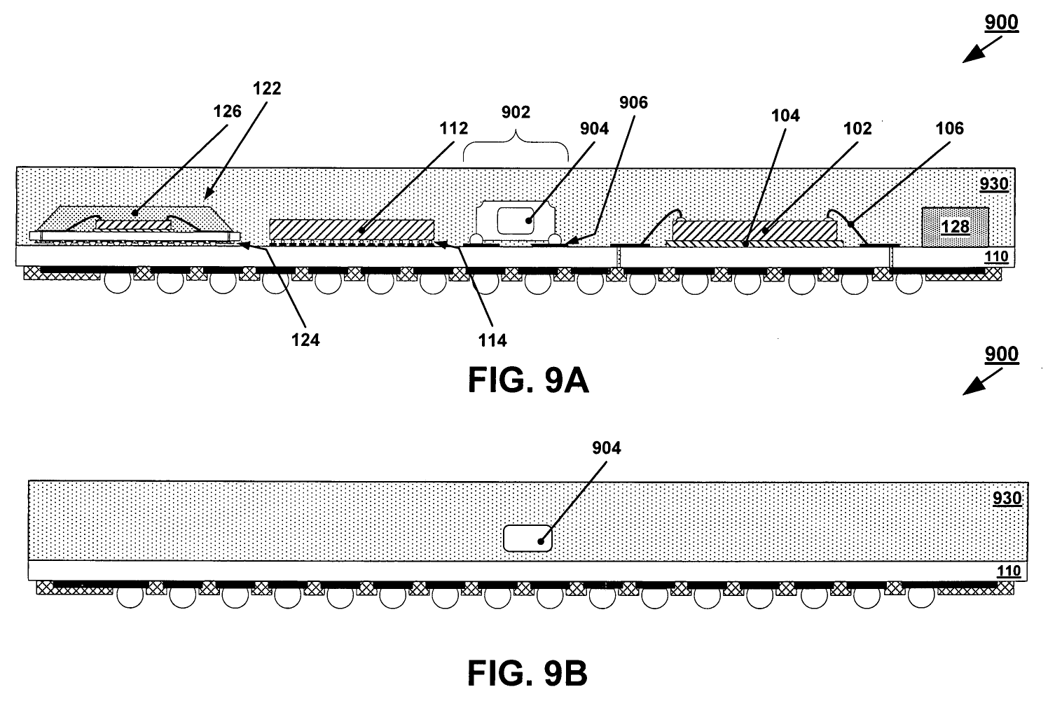

FIGS. 9A and 9B illustrate side views of an embodiment of a SiP module including an LED component, which can emit light through the side of the package to the outside of the package and/or be made visible through the side of the package. FIG. 9A shows a see-through view where internal components are shown and FIG. 9B shows an exterior view where internal components are hidden. As in the previous examples, SiP module 900 is shown comprising a representative wire bonded bare die (die 102), a representative flip chipped bare die (die 112), a representative semiconductor package (package 122) and representative passive components (128), which are all appropriately mounted onto substrate 110. Additionally, module 900 comprises comprise LED component 902 which is surface mounted using solder 906 facing sideways relative to the module 900. In the diagram, LED component 902 comprises resin 904, which faces normal to the diagram. Once molded, package 900 from the exterior shows only resin 904 visible in mold compound 930.

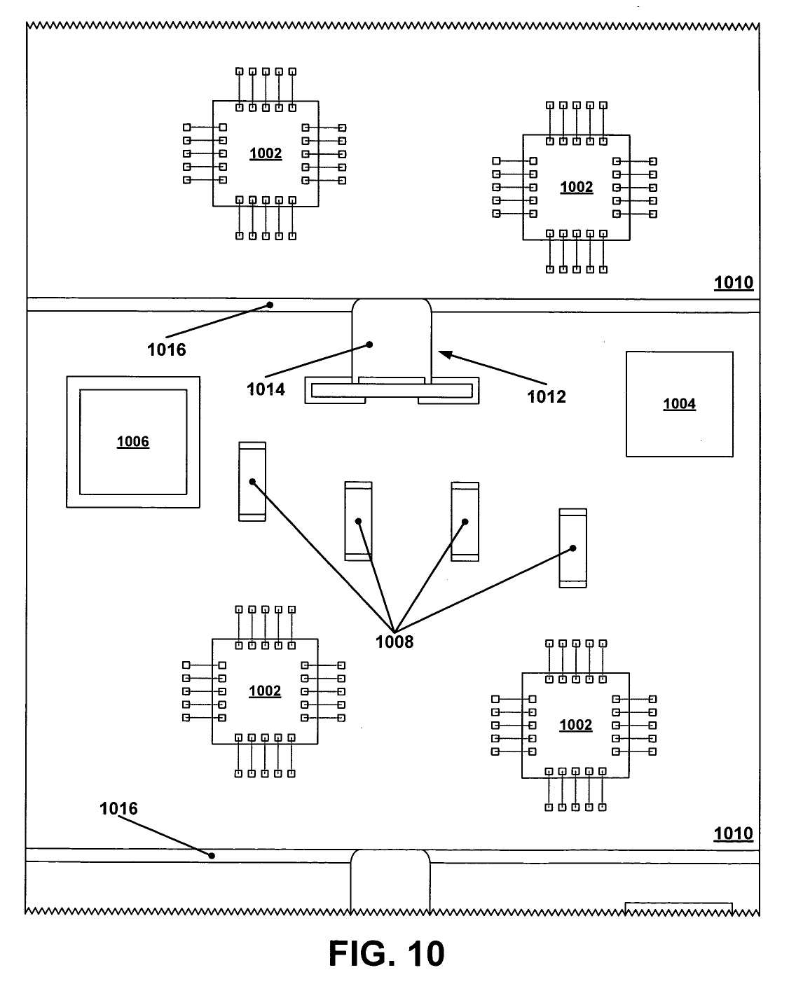

To better clarify the placement of components, FIG. 10 is a top view of an embodiment of an array of SiP modules. In each module, representative wire bonded bare dies 1002, flip chipped bare dies 1004, semiconductor packages 1006, passive components 1008 are attached to substrate 1010. Because of the two-dimensional view, the components are shown laid out in a two-dimensional fashion rather than linearly as represented in the side view. This two-dimensional layout matches more closely the realistic layout on a SiP package. Each module further comprises LED component 1012 which faces sideways away from the package. Each LED component comprises resin 1014, which is placed so that the remote end of the resin falls within kerf 1016 of the singulation saw. When the singulation saw separates the individual modules, it will remove material along kerf 1016 including substrate, mold compound and resin.

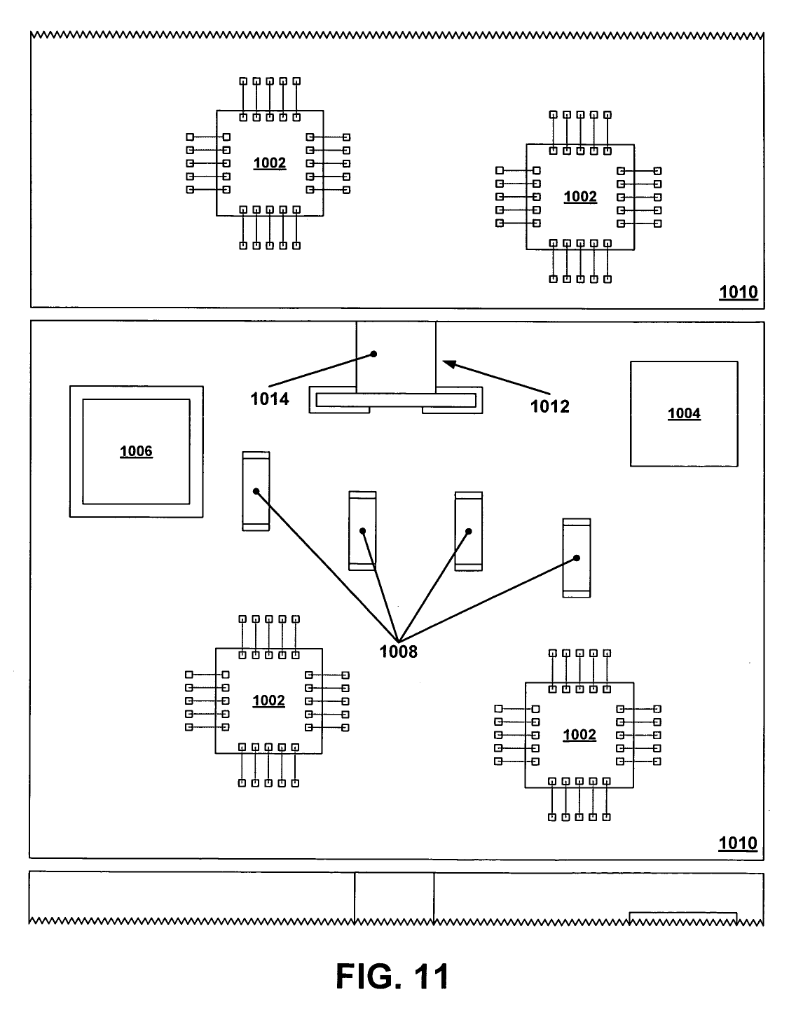

FIG. 11 is a top view of the array of SiP modules after singulation. Resin 1014 has been sawn leaving it exposed to the exterior of the package. The cutting away of material of resin 1014 does not affect the functionality of the LED.

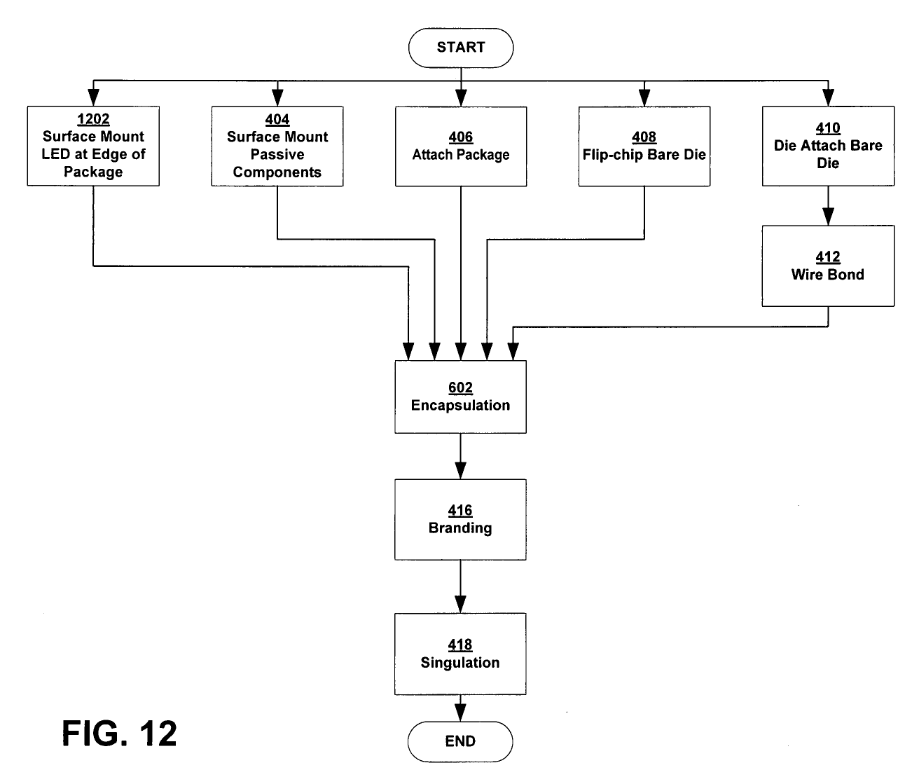

The packaging of the side view LED would require no substantial modification to an existing SiP packaging procedure, if any. The enablement of the packaging process lies in the placement of the LED component rather than altering existing steps. More specifically, FIG. 12 shows a process flow for the packaging of a SiP module with a sideways facing LED. Steps 404, 406, 408, 410, 412, 602, 416 and 418 are as described above in FIG. 4 and FIG. 6. Unlike steps 402 or step 804 described previously, at step 1202, LED components are surface mounted facing sideways at the edge of the substrate boundary, so that the resin falls into the saw kerf. The LED resin is automatically exposed during singulation at step 418.

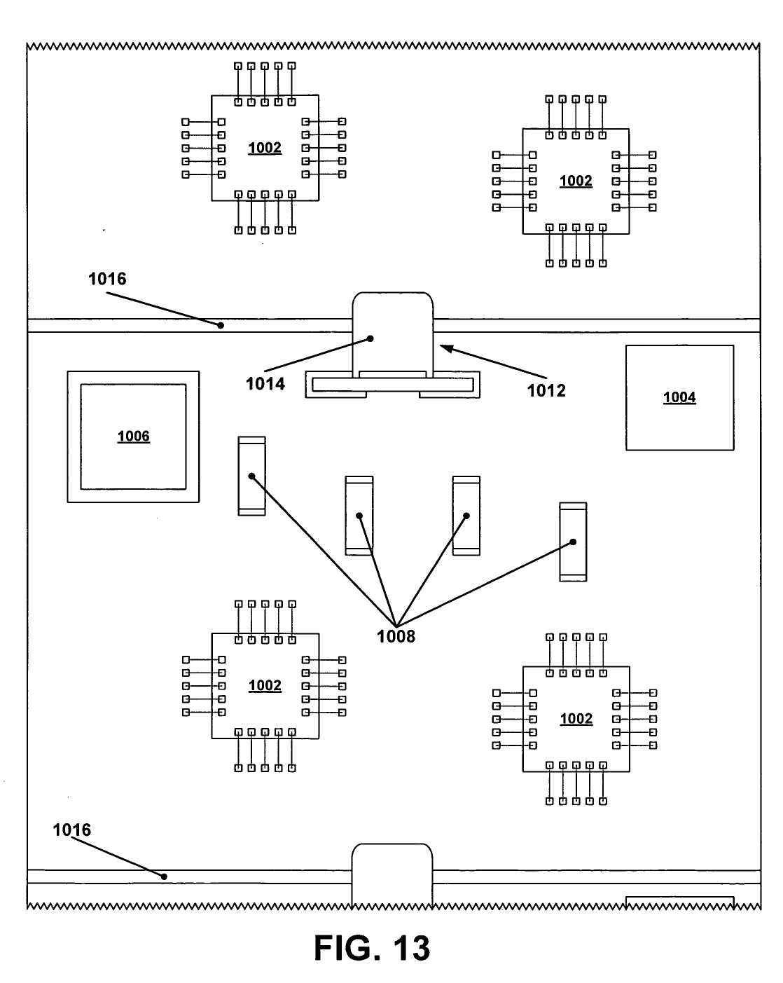

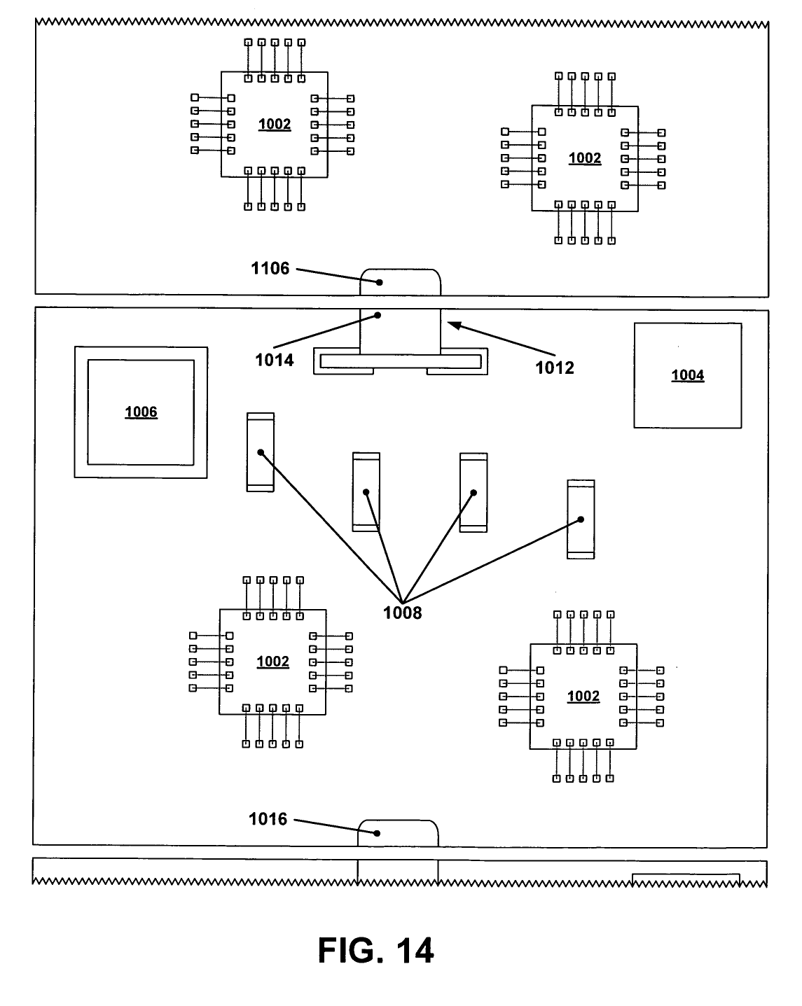

In the event that the placement of the LED cannot be made so precisely that the end of the resin falls into the saw kerf, the LED component can be placed even more outward so that the resin falls across the saw kerf. FIG. 13 is a top view of an embodiment of an array of SiP modules. Like numbered components are as described previously for FIGS. 10 and 11. In this example, LED component 1012 is placed further towards the boundary of the substrate, so that resin 1014 intrudes upon the adjacent module. FIG. 14 is a top view of the array of SiP modules after singulation. Because resin 1014 intrudes upon the adjacent module, some about of residual resin will be present shown by reference label 1402. Though this might result in an undesirable aesthetic, it does not functionally impact the package or the function of the LED. As a result, either placement of the resin edge in the saw kerf or beyond the saw kerf produces a functional package.

It should be noted that though this side view LED embodiments are described in the saw singulation process, side view LED components can also be incorporated in punch singulated SiP modules where the resin of the LED components are cleaved by a punch tool.

It should be emphasized that the above-described embodiments are merely examples of possible implementations. Many variations and modifications may be made to the above-described embodiments without departing from the principles of the present disclosure. For example, multiple LED components of various orientations can be used incorporating or combining multiple methods described. A SiP module might comprise an LED module facing upwards and another LED module facing downwards. The fabrication of this device would include making a hole in the substrate and an opening in the mold compound. All such modifications and variations are intended to be included herein within the scope of this disclosure and protected by the following claims.

What is claimed is:

1. A system-in-package (SiP) module comprising:
a substrate;
a semiconductor die attached to the substrate;
a mold compound which encapsulates the semiconductor die; and
an LED (light emitting diode) component attached to the substrate, wherein the LED component is at least partially located within the SiP module, such that the LED component can emit lights to outside of the SiP module.

2. The SiP module of claim 1, wherein the LED component has a resin facing a top surface of the SiP module and the mold compound is below a top edge of the resin.

3. The SiP module of claim 1, wherein the LED component has a resin facing a top surface of the SiP module, and wherein there is an opening in the mold compound above the resin of the LED component.

4. The SiP module of claim 1, wherein the LED component has a resin facing a bottom surface of the SiP module, and wherein there is an opening below the substrate exposing the resin.

5. The SiP module of claim 1, wherein the LED component has a resin facing a side surface of the SiP module, and wherein the resin extends to a boundary of the mold compound.

6. The SiP module of claim 1 further comprising bond wires which electrically attach the semiconductor die to the substrate.

7. The SiP module of claim 1 further comprising solder balls or metal pillars which electrically attach the semiconductor die to the substrate in a flip chip configuration.

8. The SiP module of claim 1 further comprising a semiconductor package attached to the substrate.

9. The SiP module of claim 1 further comprising a surface mounted passive component attached to the substrate.

10. The SiP module of claim 9 wherein the passive component comprises an inductor, a capacitor, a resistor, or a discrete diode.

11. A method of manufacturing a system-in-package (SiP) module, the method comprising:
providing a substrate;
attaching a semiconductor die the substrate;
encapsulating the semiconductor die with a mold compound; and
attaching an LED (light emitting diode) component to the substrate, wherein the LED component is at least partially located within the SiP module, such that the LED component can emit lights to outside of the SiP module.

12. The method of claim 11, wherein the LED component has a resin facing a top surface of the SiP module and the mold compound is below a top edge of the resin.

13. The method of claim 11, wherein the LED component has a resin facing a top surface of the SiP module, and wherein there is an opening in the mold compound above the resin of the LED component.

14. The method of claim 11, wherein the LED component has a resin facing a bottom surface of the SiP module, and wherein there is an opening below the substrate exposing the resin.

15. The method of claim 11, wherein the LED component has a resin facing a side surface of the SiP module, and wherein the resin extends to a boundary of the mold compound.

16. The method of claim 11, wherein the attaching of the semiconductor die the substrate further comprises bond wiring the semiconductor die to the substrate.

17. The method of claim 11, wherein the attaching of the semiconductor die the substrate uses solder balls or metal pillars for attaching the semiconductor die to the substrate in a flip chip configuration.

18. The method of claim 11 further comprising attaching a semiconductor package to the substrate.

19. The method of claim 11 further comprising attaching a surface mounted passive component to the substrate.

20. The method of claim 19, wherein the passive component comprises an inductor, a capacitor, a resistor, or a discrete diode.
